(19) United States
(12) Patent Application Publication
(10) Pub. No.: US 2025/0272135 A1
(43) Pub. Date: Aug. 28, 2025

(54) Real Device Validation on Hybrid Emulation Systems

(71) Applicant: Google LLC, Mountain View, CA (US)

(72) Inventors: Jyothish Balakrishnan, Ernakulam (IN); Rahul Soman, Bangalore (IN)

(73) Assignee: Google LLC, Mountain View, CA (US)

(21) Appl. No.: 19/208,259

(22) Filed: May 14, 2025

Related U.S. Application Data
(60) Provisional application No. 63/802,810, filed on May 9, 2025.

(51) Int. Cl. G06F 9/455

(52) U.S. Cl. CPC G06F 9/45558; G06F 2009/45575

(57) ABSTRACT

This document describes systems and techniques for a hybrid virtualization and emulation system for validating a hardware-specific code module. For example, a hybrid validation system includes a virtualization system including executable code configured to run on a computing system to simulate an operating environment and to communicate with a peripheral device via a hardware-specific code module executable on an intellectual property (IP) block. A hardware emulation system is operably coupled with the virtualization system and programmable as an emulated IP block to model operation of the IP block to execute the hardware-specific code module to communicate with the peripheral device.

### CROSS-REFERENCE TO RELATED APPLICATION

This application claims the benefit of U.S. Provisional Patent Application Ser. No. 63/802,810 filed on May 9, 2025, the disclosure of which is incorporated by reference herein in its entirety.

### SUMMARY

This document describes systems and techniques for a hybrid virtualization and emulation system for validating a hardware-specific code module. The virtualization system allows high-speed loading and execution of an operating environment while the hardware emulation system emulates a subsystem, controller, or other intellectual property (IP) block to engage with a peripheral device via a hardware bridge. In aspects, the emulated IP block may execute a hardware-specific code module configured to manage or otherwise communicate with the peripheral device via the hardware bridge in order to validate operation of the hardware-specific code module. Accordingly, the hardware-specific code module may be developed or validated using the emulated IP block without waiting for development of an actual hardware version of the IP block.

For example, a hybrid validation system includes a virtualization system including executable code configured to run on a computing system to simulate an operating environment and to communicate with a peripheral device via a hardware-specific code module executable on an intellectual property (IP) block. A hardware emulation system is operably coupled with the virtualization system and programmable as an emulated IP block to model operation of the IP block to execute the hardware-specific code module to communicate with the peripheral device.

This Summary is provided to introduce systems and techniques for a hybrid virtualization and emulation system for validating a hardware-specific code module, as further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques for a hybrid virtualization and emulation system for validating a hardware-specific code module are described in this document with reference to the following Drawings. The same numbers are used throughout the drawings to reference like features and components.

FIG. 1 is a block diagram of a hybrid validation system for developing and/or validating a hardware-specific code module;

FIG. 2 is a graph comparing execution times for emulating or operating a hardware device via combinations of virtualized, emulated, and/or actual devices;

FIG. 3 is a perspective view of the hybrid validation system of FIG. 1 configured to develop and/or validate a hardware-specific code module to operate a hardware device;

FIG. 4 is a perspective view of a portion of the hybrid validation system of FIG. 1 coupled with various hardware devices to test operation of hardware-specific code modules; and

FIG. 5 is a screen capture from the hybrid validation system of FIG. 1 executing one or more hardware-specific code modules.

### DETAILED DESCRIPTION

### Overview

Computer technology continues to advance rapidly, allowing for new and improved devices to be brought to consumers. While technology continues to improve, development cycles nonetheless may be time-consuming. For example, as semiconductor technologies continue to allow for smaller and denser processor and memory technologies, it nonetheless may require months or years to develop newer devices and to produce actual silicon-based hardware devices. Although drivers and hardware-specific code modules cannot actually be tested and debugged until actual hardware devices have been manufactured, various simulation or emulation environments may be used to develop and validate operation of hardware-specific code modules while awaiting access to the actual hardware devices. As a result, the hardware-specific code modules can be developed and/or validated without waiting for the actual hardware devices to be made available. Thus, development of the hardware-specific code modules can proceed while production of the actual hardware is still in process.

Various hardware emulation systems exist. For example, hardware emulation devices allow for modeling a hardware device, such as a subsystem, controller, or other intellectual property (IP) block in a programmable hardware array. Being able to emulate an IP block in actual hardware allows for realistic development and validation of hardware-specific code modules designed to execute on the IP block. The emulation system can then be coupled by a high-speed bridge to an existing peripheral device, such as a Wi-Fi® module, a Bluetooth® communications module, a memory device, or another peripheral device, to validate whether the hardware-specific code module executing on the emulated IP block interacts with the peripheral device as intended.

However, hardware emulation systems, although flexible in allowing for modeling of hardware devices, operate relatively slowly as compared to software-based virtualization systems. For example, in attempting to model a complete computing device, such as a mobile telephone, the hardware emulation system would have to load an operating system, such as loading the Android® Operating System, produced by Google® LLC, or an iPhone Operating System® (iOS®), produced by Apple Computer®, Inc. However, it may take orders of magnitude longer for the operating system to load and execute on the hardware emulation system than it would on a software-based virtualization system. On the other hand, if one were to try to emulate operation of the mobile telephone and the IP block under development in a software-based virtualization system, it would not be able to emulate the IP block in hardware or be able to interact with the peripheral on a hardware level.

In aspects, systems and techniques for a hybrid virtualization and emulation system for validating a hardware-specific code module achieve the advantages of both a hardware-based emulation system (hereinafter, “emulation system”) and a software-based virtualization system (hereinafter, “virtualization system”). By combining a virtualization system and an emulation system, the virtualization system can load and execute an operating system—which it can do much faster than the emulation system—while the emulation system can emulate the IP block and interact on a hardware level with a peripheral via a hardware bridge coupled with the peripheral which can, as desired, interact via a communications medium with other peripherals. Thus, such a hybrid validation system provides advantages of both virtualization and emulation systems in developing and validating a hardware-specific code module to execute on an IP block. As a result, hardware-specific code modules can be developed and validated while the actual IP block is still in development and production, instead of waiting for the IP block to be developed before the hardware-specific code module can be validated. Therefore, the parallel hardware and software development afforded by the hybrid virtualization and emulation system may cut months from the combined development cycle of the IP block and the hardware-specific code module.

### Overview of Hybrid Validation System

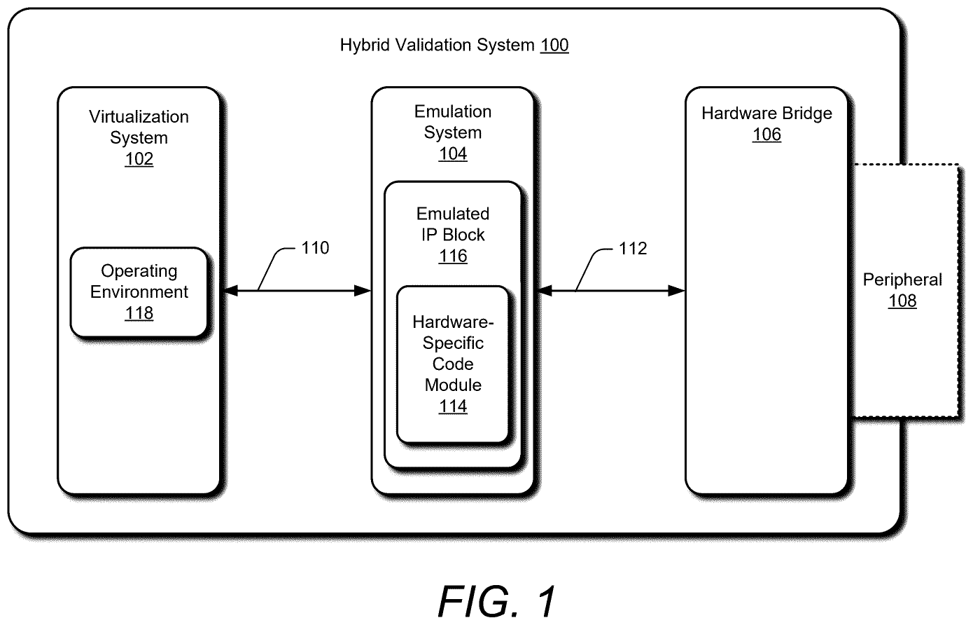

FIG. 1 shows a block diagram of a hybrid validation system 100 that includes a software-based virtualization system 102, a hardware-based emulation system 104, and a hardware bridge 106. The hardware bridge 106, which may include external wiring harnesses and couplings, receives and/or is coupled with a peripheral 108. The virtualization system 102 is coupled with the emulation system 104 with a virtualization-emulation interface 110. The emulation system 104 is coupled with the hardware bridge 106 with an emulation-bridge interface 112. For purposes of this description, the hybrid validation system 100 is used to develop and/or validate a hardware-specific code module 114 to execute on a hardware IP block that is emulated in the emulation system 104 in an emulated IP block 116. The IP block represented by the emulated IP block 116 is for use with an operating environment 118 which may include an operating system and other system software for a mobile telephone or another system (not shown).

The virtualization system 102 loads and executes the operating environment 118. Executing the operating environment 118 may include executing code that engages the peripheral 108 to perform operations, such as communicating with other devices, performing memory or storage operations, or other peripheral functions. In aspects, the virtualization system 108 manages operation of the peripheral 108 through the IP block that is represented by the emulated IP block 116, which operates according to the hardware-specific code module 114. The hardware-specific code module 114 thus facilitates control of the peripheral 108. Validating proper operation of the hardware-specific code module 114 using the hybrid validation system 100 thus allows for the hardware-specific code module 114 to be ready when the IP block hardware is ready for use.

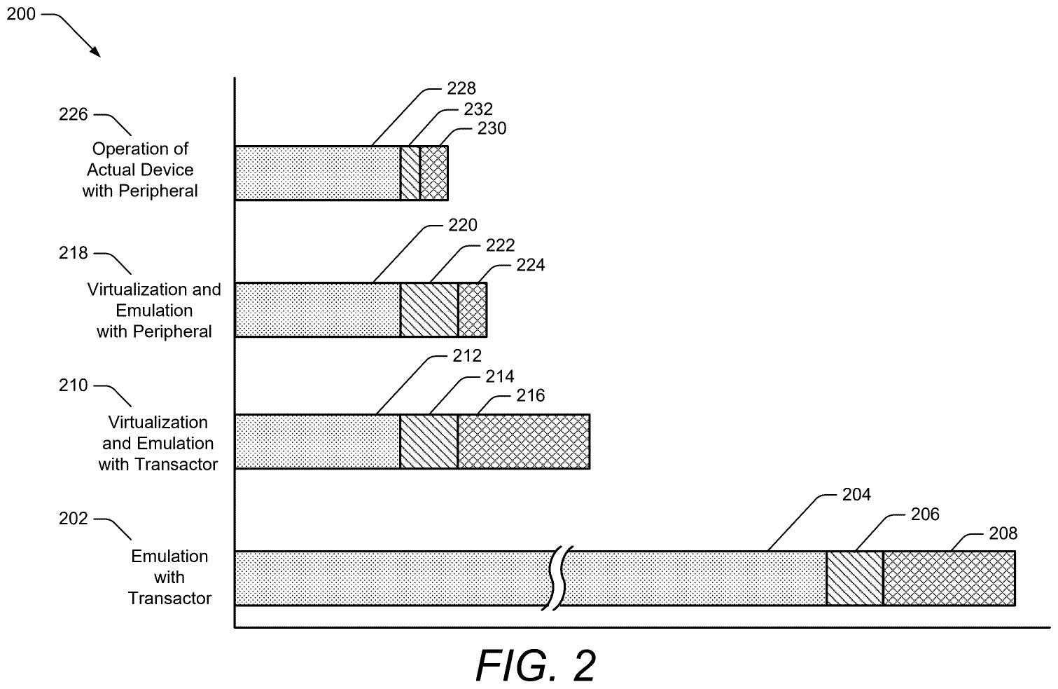

As previously mentioned, the hardware validation system 100 allows for the validation of the hardware-specific code module 114 to be completed efficiently in an emulated hardware environment. FIG. 2 shows a graph 200 comparing execution times for comparing execution times for emulating or operating a hardware device via combinations of virtualized, emulated, and/or actual devices. The graph 200 thus illustrates the efficiency advantage of the hardware validation system 100.

The graph 200 represents the relative efficiency of four different validation environments represented by stacked bar graphs. An emulation with transactor environment 202 represents validation of the hardware-specific code module 114 (see FIG. 1) in which the entire simulation is performed using hardware emulation, like the emulation system 104 including the use of a transactor that simulates operation of the peripheral 108. The emulation with transactor environment 202 includes a lengthy operating system boot-up phase 204 that, as previously described, may be comparatively very slow compared to execution in a virtualization system 102. The operating system boot-up phase 204 in the emulation with transactor environment 202 may be very lengthy compared to other phases depicted in FIG. 2 and, thus, is shown as truncated. A hardware emulation phase 206 represents a time for the hardware-specific code module 114 to execute in directing operations from the operating system to the peripheral. A transactor phase 208, which represents an amount of time for the transactor to emulate operation of the peripheral 108 in the emulation system 104, performs the operations of the peripheral directed by the operating system. The emulation with transactor environment 202 is the most time-consuming environment which may significantly slow development and/or validation of the hardware-specific code module 114.

The virtualization and emulation with transactor environment 210 uses the virtualization system 102 to execute the operating system. An operating system boot-up phase 212 thus is much faster than the operating system boot-up phase 204 in the emulation with transactor environment 202. A hardware emulation phase 214 and a transactor phase 216 may be the same as the hardware emulation phase 206 and the transactor phase 208 in the emulation with transactor environment 202. Nonetheless, the time savings afforded by combining the virtualization system 102 with the emulation system 104 saves significant time with its shortened operating system boot-up phase 212.

Efficiency may be increased further by combining the hardware bridge 106 and the peripheral 108 with the virtualization system 102 and the emulation system 104. The actual peripheral 108 operates more quickly than a transactor emulating operation of the peripheral. Thus, in a virtualization and emulation with peripheral environment 218, an operating system boot-up phase 220 and the hardware emulation phase 222 are the same as the operating system boot-up phase 212 and the hardware emulation phase 214 in the virtualization and emulation with transactor environment 210. However, the actual peripheral phase 224 is faster than the transactor phase 208 and 216, further improving development and validation time.

An operation of actual device with peripheral environment 226 represents a validation operation once the actual hardware emulated by the emulation system 104 is available. An operating system boot-up phase 228, for the sake of example, is assumed to be the same as operating system boot-up phase 220 as in the operating system boot-up phase virtualization and emulation with peripheral environment 218. A peripheral phase 230 also is the same as the peripheral phase 224 as in the operating system boot-up phase virtualization and emulation with peripheral environment 218. A hardware execution phase 232 may be faster than the hardware emulation phase 222 of the virtualization and emulation with peripheral environment 218. Nonetheless, a hybrid validation system 100 (see FIG. 1) may perform nearly as quickly as the actual device with peripheral environment 226 without having to wait for however long it might take to produce the actual hardware device that represents the IP block that manages operation of the peripheral 108.

### Example of Hybrid Validation Environment

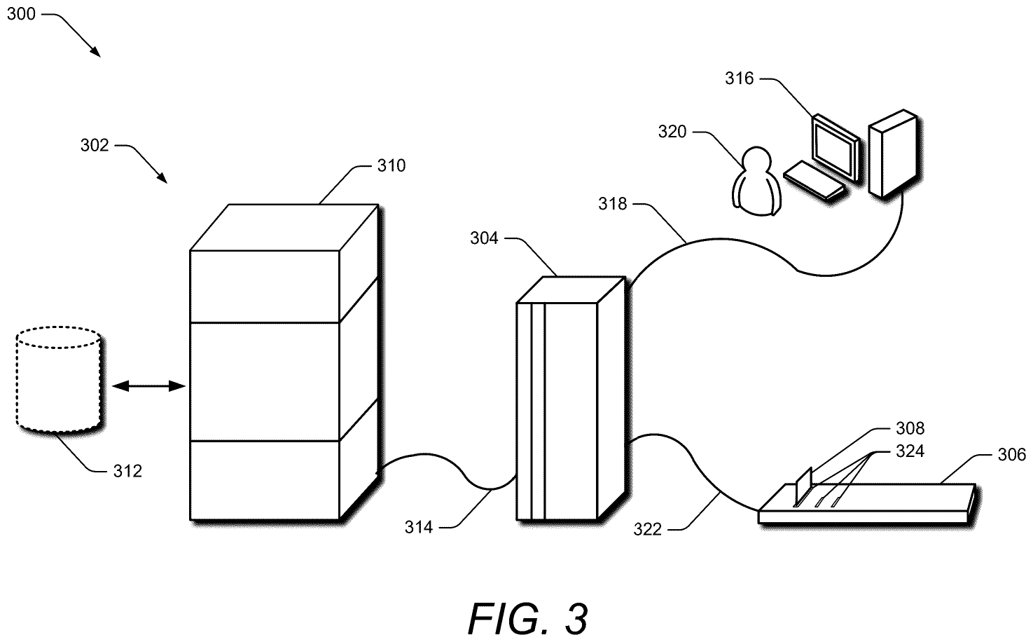

FIG. 3 shows an example hybrid validation system 300. Analogous to the block diagram of the hybrid validation system 100 (see FIG. 1), the hybrid validation system 300 includes a virtualization system 302, an emulation system 304, and a hardware bridge 306 that engages a peripheral 308 for development and validation.

The validation system 302 may include a general-purpose workstation 310 that accesses and runs executable code 312 that provides the virtualization system. For example, commercially-available systems provide a software suite that may be adapted to provide a software model of a computing system, such as a mobile telephone or any other device. The workstation 310 may include an Ethernet adapter (not shown) which, via a wired connection 314 or a wireless connection (not shown) may communicate with the emulation system 304.

The emulation system 304 may be controlled by a dedicated workstation 316 coupled to the emulation system 304 via a wired connection 318, such as an Ethernet connection, and used by a programmer 320 to establish a configuration file (not shown) that constitutes the emulated IP block 116 (see FIG. 1).

The hardware bridge 306 may require a Physical Interface for Peripheral Component Interface Express (PIPE 4.4.1 PCIe) interface over a high-speed wired connection 322, such as a magnesium diboride (MGB2) superconducting cable or a small form-factor pluggable (SFP) fiber-optic connector to accommodate circuit-level, high-speed communication with the peripheral device 308. The hardware bridge 306 may, through built-in or separate hardware interfaces 324, engage with the peripheral 308.

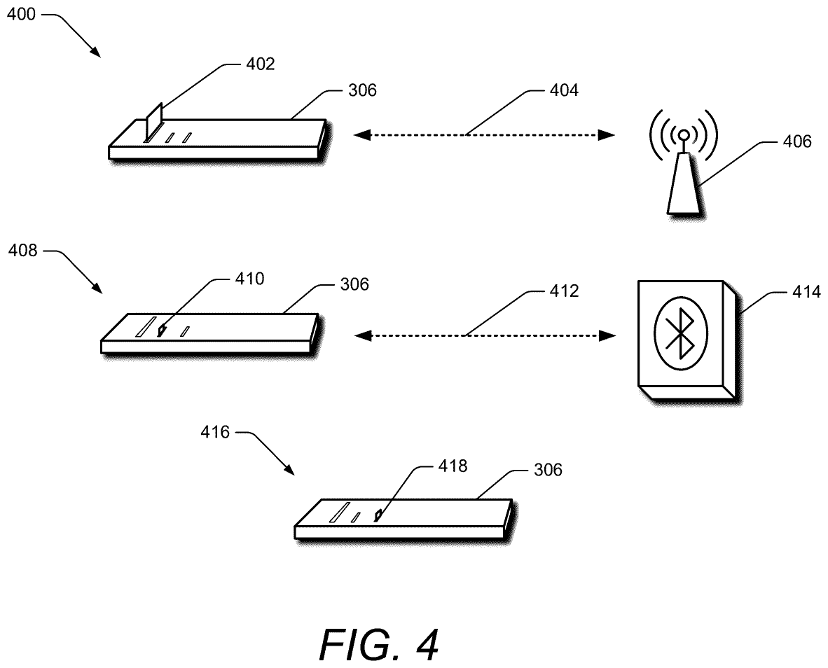

FIG. 4 shows various peripheral devices 400, 402, and 404 that may be received by the hardware bridge 306 for testing of the hardware-specific code module 114 executing on the emulated IP block 116 (see FIG. 1). As previously described, a benefit of the hybrid validation system 100 is to be able to test actual peripherals, such as communications or memory devices, to ensure that the hardware-specific code module will operate as desired. The use of the actual peripherals also enables the peripherals to be tested with any devices with which the peripherals interact.

For example, in example 400, the hardware bridge 306 may receive an IEEE 802-type Wi-Fi® communications device 402. Data and commands directed to the Wi-Fi® communications device 402 from the hardware-specific code module 114 executing on the emulated IP block 116 (see FIG. 1) are passed to the Wi-Fi® communications device 402. In response, the Wi-Fi® communications device 402 may establish Wi-Fi® communications 404 with an external Wi-Fi® communications device 406, such as a Wi-Fi® router or access point. Thus, the hardware-specific code module 114 executing on the emulated IP block 116 may be tested under actual conditions to validate that the Wi-Fi® communications device 402 is properly able to send data to and receive data from the external Wi-Fi® communications device 406.

Similarly, in example 408, the hardware bridge 306 may receive a Bluetooth® communications device 410. Data and commands directed to the Bluetooth® communications device 410 from the hardware-specific code module 114 executing on the emulated IP block 116 are passed to the Bluetooth® communications device 410. In response, the Bluetooth® communications device 410 may establish Bluetooth® communications 412 with another Bluetooth® device 414. Thus, the hardware-specific code module 114 executing on the emulated IP block 116 may be tested under actual conditions to validate that the Bluetooth® communications device 410 is properly able to send data to and receive data from the external Bluetooth® device 414.

In aspects, the hybrid validation system also may be used to validate a hardware-specific code module 114 executing on the emulated IP block 116 with peripherals other than communications devices. In example 416, the hardware bridge 306 receives a memory and/or storage device 418 that the hardware-specific code module 114 executing on the emulated IP block 116 is developed to manage storage and/or retrieval from the memory and/or storage device 418. The hybrid validation system 100 thus may be used to validate that the hardware-specific code module 114 executing on the emulated IP block 116 is able to properly store data to and retrieve data from the memory and/or storage device 418.

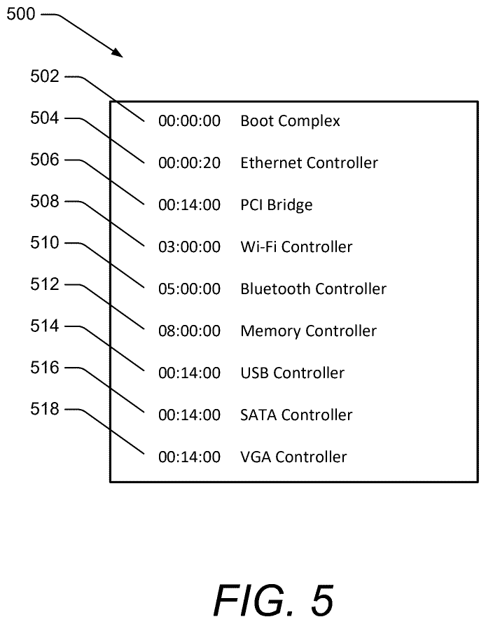

FIG. 5 is a screen capture 500 from the hybrid validation system of FIG. 1 executing one or more hardware-specific code modules to test peripheral devices. The screen capture 500, taken from the workstation 302 (see FIG. 3) executing the virtualization system 102 (see FIG. 1) shows peripheral devices 106 with which the one or more hardware-specific code modules 114 executing on the emulation system 104. The hybrid validation system 100 allows the virtualization system 102 to see and monitor the peripherals as though they are physically coupled to actual hardware devices and not just emulated IP blocks 116.

The screen capture 500 shows initiation of the boot complex 502 and connection to the Ethernet controller 502 that couples the virtualization system 102 to the emulation system 104. The screen capture 500 then shows connection to the PCI bridge 506, that may be coupled to the virtualization system 102 via the emulation system 104 and one or more hardware-specific code modules 114. Then, through the execution of one or more hardware-specific code modules executing on one or more emulated IP blocks 116, the screen capture 500 displays the peripheral devices as though coupled through IP blocks being emulated. The virtualization system can “see” and interact with a Wi-Fi controller 508 and a Bluetooth controller 510 like those in the examples 400 and 408 of FIG. 4, respectively. The virtualization system can engage a memory controller 512 that may be used with a memory device 418 like that in the example 416. Hardware-specific code modules for other devices also may be created and validated, such as a universal serial bus (USB) controller 514, a serial advanced technology attachment (SATA) controller 516, a video graphics array (VGA) controller 518, or other devices.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although implementations of systems and techniques for a hybrid virtualization and emulation system for validating a hardware-specific code module have been described in language specific to certain features and/or methods, the subject of the appended claims is not necessarily limited to the specific features or methods described. Rather, the specific features and methods are disclosed as example implementations of systems and techniques for a hybrid virtualization and emulation system for validating a hardware-specific code module.

What is claimed is:

1. A hybrid validation system comprising:
a virtualization system including executable code configured to run on a computing system to simulate an operating environment and to communicate with a peripheral device via a hardware-specific code module executable on an intellectual property (IP) block; and
a hardware emulation system operably coupled with the virtualization system and programmable as an emulated IP block to model operation of the IP block to execute the hardware-specific code module to communicate with the peripheral device.

2. The system of claim 1, further comprising a hardware bridge operably coupled with the hardware emulation system and to be operably coupled with the peripheral device, the virtualization system being able to interact with the peripheral device via the hardware-specific code module executing on the emulated IP block to validate operation of the hardware-specific code module.

3. The system of claim 1, wherein the operating environment includes a mobile device operating system.

4. The system of claim 3, wherein the mobile device operating system includes Android® or iPhone Operating System® (iOS®).

5. The system of claim 2, wherein the emulated IP block simulates a control device for the peripheral device.

6. The system of claim 5, wherein the hardware-specific code module includes a driver for the peripheral device.

7. The system of claim 6, wherein the hardware bridge and the hardware device are interfaceable using a Peripheral Computer Interconnect Express (PCIe) interface.

8. The system of claim 1, wherein the peripheral includes a communications device.

9. The system of claim 8, wherein the communications device includes a Wi-Fi® communications device or a Bluetooth® communications device.

10. The system of claim 1, wherein the peripheral includes a memory device.
